(19) United States
(12) Patent Application Publication
(10) Pub. No.: US 2024/0389237 A1
(43) Pub. Date: Nov. 21, 2024

(54) SUBSTRATELESS HYBRID POWER MODULE ASSEMBLY AND METHOD FOR FABRICATING THEREOF

(71) Applicant: IndiaVP Semiconductor Pvt Ltd, MRC Nagar, Chennai (IN)

(72) Inventor: VIJAY BOLLOJU BOLLOJU, BENGALURU (IN)

(73) Assignee: IndiaVPSemiconductor Pvt Ltd., MRC Nagar, Chennai (IN)

(21) Appl. No.: 18/690,715

(22) PCT Filed: Sep. 6, 2022
(86) PCT No.: PCT/IB2022/058368

§ 371 Date: Mar. 8, 2024

(30) Foreign Application Priority Data
Sep. 8, 2021 (IN) 202141040790

(51) Int. Cl. H05K 1/18; H05K 1/02; H05K 3/28; H05K 3/30

(52) U.S. Cl. CPC H05K 1/181; H05K 1/0204; H05K 3/28; H05K 3/303; H05K 2201/10272

(57) ABSTRACT

Embodiments herein disclose a method for fabricating a substrateless hybrid power module assembly. The method includes providing a PCB (1302). Further, the method includes assembling a control circuit component on the PCB (1302). Further, the method includes attaching a power device on the control circuit component Further, the method includes performing device interconnects on the deice using SMT a wire bonding and/or a copper strap. Further, the method includes attaching a busbar on a bottom portion of the PCB (1302). Further, the method includes attaching an isolation layer (1312) below the busbar attached on the bottom portion of the PCB (1302). Further, the method includes attaching a heat dissipating layer (1314) below the isolation layer (1312). Further, the method includes attaching one of a plastic moulding case (2702) and a potting compound on the heat dissipating layer (1314).

### TECHNICAL FIELD

Embodiments disclosed herein relate to a power module assembly, and more particularly to related to a flexible, substrateless high current power module assembly and a method for assembling/fabricating the substrateless hybrid power module assembly.

### BACKGROUND

Emerging industrial, automotive and consumer electronics applications demand high power density and high efficiency for the systems at a reasonable cost. Flexibility of design and assembly is key to meet varying product demands. The central criteria for a reliable electronics design is thermal management. For improving reliability of the electronics, the peak temperatures of the components need to be maintained to the lowest possible limits.

The usual practice for designing a high power, high current electronic module is to use high thermal conductivity materials such as ceramic substrates to attach the power devices. This ensures improved thermal path for the dissipated heat by the electronic devices to the ambient. The common materials used for this purpose are Aluminium oxide (Al₂O₃), Aluminium nitride (AlN), aluminum silicon carbide (AlSiC) ceramic substrates or Aluminium metal core printed circuit board (PCBs). While ceramic substrates have high thermal conductivity compared to a Flame Retardant 4 (FR4) PCBs, they are expensive and need complex sintering processes to print the circuit patterns. The thickness of copper traces that can be economically printed on the ceramic substrates is limited to about 100 μm. This thickness may not be sufficient to reliably carry the high currents required by the systems. The user can attach copper lead frames of desired thicknesses to fulfil the needs. But this process increases the component count, complexity, and the cost of the system.

Mounting power devices such as metal-oxide-semiconductor field-effect transistor (MOSFETs), insulated-gate bipolar transistor (IGBTs), Diodes etc. on the FR4 PCB is the easiest and most economical method. However, the FR4 material has incredibly low thermal conductivity (0.24 W/m-°K) and hence it would severely limit the utilization of the power device's capabilities. The low melting temperature of the FR4 also imposes further limitations. As the currents in the system increases, the thickness of the copper traces required will also be a constraint. An Aluminium core PCB has better thermal conductivity compared to the FR4 PCB, but it also has limitations on the thickness of the copper traces. The printing thicker copper traces increases the cost of the manufacturing. Alternatively, thicker copper lead frames may be attached to increase the current carrying capacity. But this method has the same drawbacks (e.g., component count, complexity, and the cost of the system, etc.).

Alternatively, the user of the system can use discrete semiconductors mounted directly on a heat sink to improve the performance. However, as the voltage and current increases, the complexity of the assembly, variances and increased parasitic would reduce the productivity and reliability. As the power ratings increase, several power devices may need to be connected in parallel. This makes the system complex and reduces the reliability. It is recommended to use Integrated Power Modules (PM) and Intelligent Power Modules (IPM) for such applications. They make the system integration easier, reduces the variances and improves the reliability of the system.

FIG. 1 and FIG. 2 are example illustrations (100 and 200) in which Surface-mount technology (SMT) devices mounted on the FR4 PCB is depicted. The FR4 PCB has very low thermal conductivity. This derates the power device performance and hence the designer needs to use many devices in parallel to achieve the desired performance specifications. The copper trace thickness is limited to about 200 microns. This poses challenges to conduct high currents required by the system. Using multiple layer (>2 layers) increases complexity and cost of manufacturing the FR4 PCBs.

FIG. 3 is an example illustration (300) in which the SMT devices mounted on a metal core PCB is depicted. The Metal core PCBs are usually single layer and hence difficult to implement both power and control circuit on the same substrate. The thickness of the copper traces is limited to about 200 microns. For higher current systems an additional copper lead frame to be attached leading to complexity and low reliability of the system.

FIG. 4 illustrates a cross sectional view (400) of the metal core PCB. As shown in the FIG. 4, an insulation layer is provided on a portion of an Al core and a copper layer is provided on a portion of the insulation layer.

FIG. 5 illustrates a cross sectional view (500) of a module with a ceramic substrate. FIG. 6 illustrates a cross sectional view (600) of the ceramic substrate. The ceramic substrates are precision engineered components and are expensive. The ceramic substrates are useful in systems with voltages exceeding 1200V. The ceramic substrates are usually singles sided and hence it is difficult to place both power devices and control circuit on the same substrate. The thickness of the copper traces is limited to about 200 microns. For higher current systems an additional copper leadframe to be attached leading to complexity and low reliability of the system. As shown in the FIG. 6, a top copper layer is provided on a portion of a ceramic insulation layer. The ceramic insulation layer is provided on a bottom copper layer. The ceramic insulation layer is placed between the top copper layer and the bottom copper layer.

FIG. 7a to FIG. 7C are example illustrations (700a-700c) in which insert moulded lead frame design concepts are depicted. This approach does not use ceramic substrates. This method employs direct molding of lead frames in the plastic base. This is a low-cost option with possibility of using thicker lead frames. The drawbacks of this method are difficulty in keeping the lead frames planar to the heat sink. Moisture leakage though the gaps between the lead frame and plastic molding. Difficult to embed very fine traces required for embedding the control circuit components alongside the power devices.

Thus, it is desired to address the above-mentioned disadvantages or other shortcomings or at least provide a useful alternative.

### OBJECTS

The principal object of embodiments herein is to disclose a method for assembling/fabricating a flexible, substrateless hybrid power module assembly.

Another object of embodiments herein is to improve effectiveness, reliability, productivity of power electronics systems assembled using discrete power devices and/or a bare dice in a high power electronic system.

Another object of embodiments herein is to create custom high current power modules (PM) and Intelligent Power Modules (IPM) without the use of expensive ceramic substrates.

Another object of embodiments herein is to eliminate complex processes, expensive, long lead time materials and allows for high density integration while improving the thermal performance of the flexible, substrateless hybrid power module assembly.

Another object of embodiments herein is to combine a control circuit and a power circuit seamlessly and enable high degree of integration of the electronic system while improving the power density, thermal performance and the reliability of the flexible, substrateless hybrid power module assembly.

Another object of embodiments herein is to allow a traditional SMT mounting technique, aluminium wire bonds, copper strip bonding solderable interconnection methods or any interconnect methods to make a circuit. These features make the proposed method enabling a wide range of products and applications. It also maximizes the utilization of power device capabilities and reduce the cost of power delivery. The method allows for flexible designs and quick time to market and to achieve optimized cost of the solutions.

These and other aspects of the embodiments herein will be better appreciated and understood when considered in conjunction with the following description and the accompanying drawings. It should be understood, however, that the following descriptions, while indicating at least one embodiment and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF FIGURES

Embodiments herein are illustrated in the accompanying drawings, through out which like reference letters indicate corresponding parts in the various figures. The embodiments herein will be better understood from the following description with reference to the drawings, in which:

FIG. 1 and FIG. 2 are example illustrations in which SMT devices mounted on a FR4 PCB is depicted, according to prior art;

FIG. 3 is an example illustration in which the SMT devices mounted on a metal core PCB is depicted, according to prior art;

FIG. 4 illustrates a cross sectional view of a metal core PCB, according to prior art;

FIG. 5 illustrates a cross sectional view of a module with ceramic substrate, according to prior art;

FIG. 6 illustrates a cross sectional view of the ceramic substrate, according to prior art;

FIG. 7a to FIG. 7C are example illustrations in which insert moulded lead frame design concepts are depicted, according to prior art;

FIG. 8 is an example illustration in which substrateless hybrid power module with SMT power devices is depicted, according to embodiments as disclosed herein;

FIG. 9 is another schematic circuit diagram of the substrateless hybrid power module with the power devices, according to embodiments as disclosed herein;

FIG. 10 is an example illustration in which the substrateless hybrid power module with a chip and a wire bonding is depicted, according to embodiments as disclosed herein;

FIG. 11 is an example illustration in which the substrateless hybrid power module with copper strap interconnects using a Solderable Front Metal (SFM) die is depicted, according to embodiments as disclosed herein;

FIG. 12 is an example illustration in which the substrateless hybrid power module PCB windows cut out under power devices is depicted, according to embodiments as disclosed herein;

FIG. 13 illustrates a cross sectional view of the substrateless hybrid power module, according to embodiments as disclosed herein;

FIG. 14 is an example illustration in which the substrateless hybrid power module with integrated embossed heatsink is depicted, according to embodiments as disclosed herein;

FIG. 15 illustrates a cross sectional view of the hybrid power module with substrates, according to embodiments as disclosed herein;

FIG. 16 is an example illustration in which a substrateless hybrid power module with the SMT power devices is depicted, according to embodiments as disclosed herein;

FIG. 17 is another example illustration in which the substrateless hybrid power module with the chip and the wire bonding is depicted, according to embodiments as disclosed herein;

FIG. 18 is another example illustration in which the substrateless hybrid power module with copper strap interconnects using the SFM die is depicted, according to embodiments as disclosed herein;

FIG. 19 is an example illustration in which the substrateless hybrid power module a PCB windows cut out under the power devices is depicted, according to embodiments as disclosed herein;

FIG. 20 illustrates a cross sectional view of the substrateless hybrid power module with the chip and wire bonding, according to embodiments as disclosed herein;

FIG. 21 is an example illustration in which substrateless hybrid power module, according to embodiments as disclosed herein;

FIG. 22 is an example illustration in which the substrateless hybrid power module with the SMT power devices is depicted, according to embodiments as disclosed herein;

FIG. 23 is an example illustration in which the substrateless hybrid power module with the chip and wire bonds is depicted, according to embodiments as disclosed herein;

FIG. 24 is another example illustration in which the substrateless hybrid power module with the copper strap interconnects using the SFM die is depicted, according to embodiments as disclosed herein;

FIG. 25 is an example illustration in which the substrateless hybrid power module PCB with cutouts is depicted, according to embodiments as disclosed herein;

FIG. 26 illustrates a cross sectional view of the substrateless hybrid power module embossed copper bus bars, according to embodiments as disclosed herein;

FIG. 27 illustrates a cross sectional view of the substrateless hybrid power module, according to embodiments as disclosed herein;

FIG. 28 is an example illustration in which the substrateless hybrid power module with molded plastic casing is depicted, according to embodiments as disclosed herein;

FIG. 29 is schematic circuit diagram of a 3-phase inverter power circuit, according to embodiments as disclosed herein;

FIG. 30 is an example illustration in which 3-phase inverter power module concept separately attached power terminals with SMT devices is depicted, according to embodiments as disclosed herein;

FIG. 31 is an example illustration in which the 3-phase inverter power module integrated power terminals with SMT devices is depicted, according to embodiments as disclosed herein;

FIG. 32 is an example illustration in which the 3-phase inverter power module separately attached power terminals with chip and wire, according to embodiments as disclosed herein;

FIG. 33 is an example illustration in which the 3-phase inverter power module integrated power terminals with bare die or chip and wire bonding, according to embodiments as disclosed herein;

FIG. 34 is an example illustration in which a full bridge topology with bare die/chip and wire bonds is depicted, according to embodiments as disclosed herein;

FIG. 35 is circuit diagram of the full bridge topology with a bare die/chip and wire bonds, according to embodiments as disclosed herein;

FIG. 36 is an example illustration in which a half bridge topology with bare die/chip and wire bonds is depicted, according to embodiments as disclosed herein;

FIG. 37 is circuit diagram of a half bridge topology with bare die/chip and wire bonds, according to embodiments as disclosed herein;

FIG. 38 is an example illustration in which a bidirectional switch with bare die/chip and wire bonds is depicted, according to embodiments as disclosed herein;

FIG. 39 is circuit diagram of a bidirectional switch with bare die/chip and wire bonds is depicted, according to embodiments as disclosed herein;

FIG. 40 is front view of a lead frame assembly, according to embodiments as disclosed herein;

FIG. 41 is a side view of a lead frame assembly along with details, according to embodiments as disclosed herein;

FIG. 42 is an example illustration in which the lead frame assemble on FR4 PCB is depicted, according to embodiments as disclosed herein;

FIG. 43 is a cross sectional view of bidirectional switch assembly stack details, according to embodiments as disclosed herein; and

FIG. 44-FIG. 48 are flow charts illustrating a method for assembling the substrateless hybrid power module assembly, according to embodiments as disclosed herein.

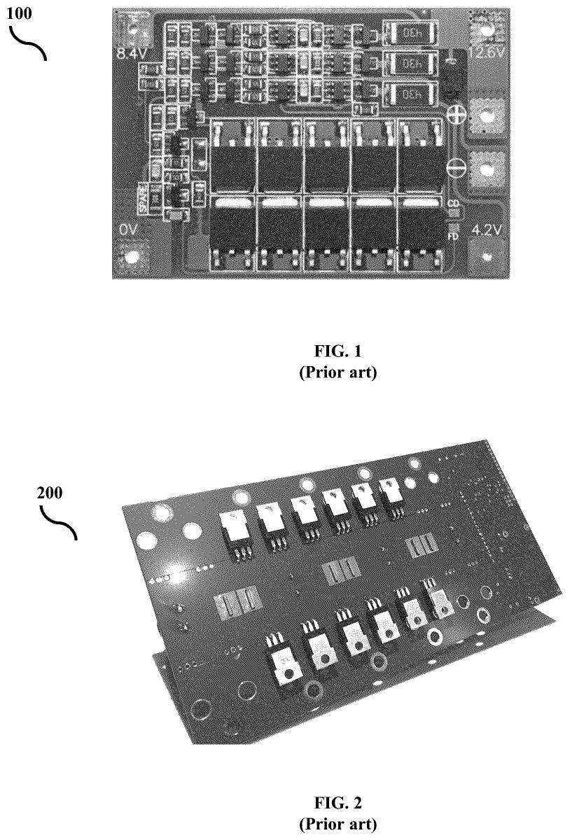

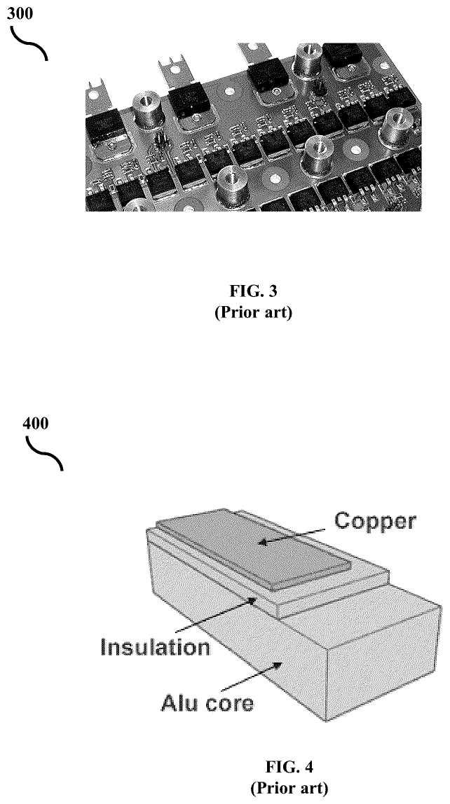

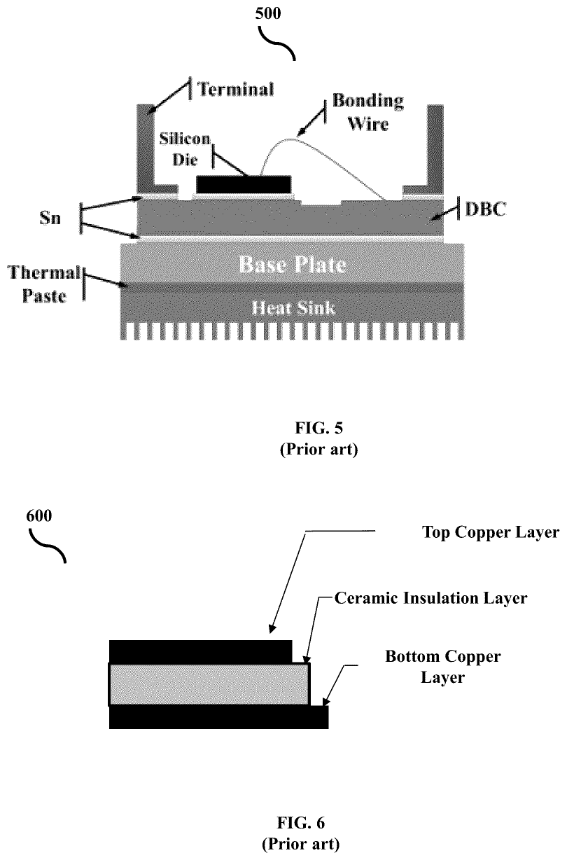

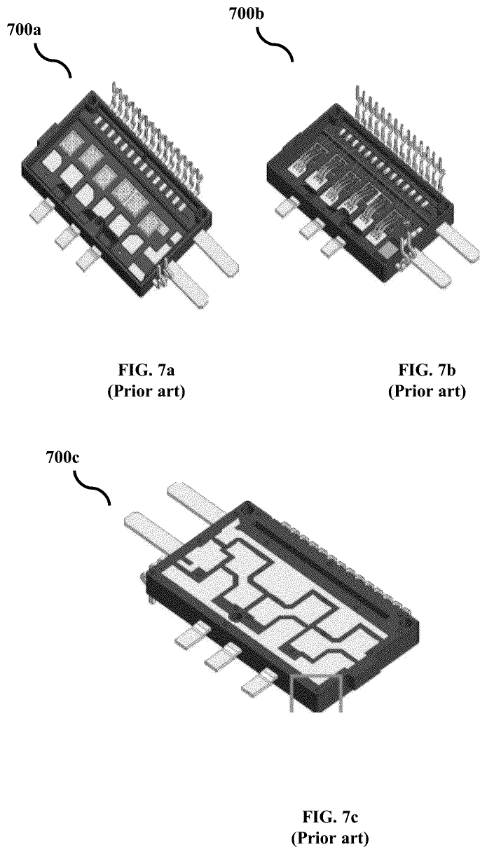

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The embodiments herein achieve a method for assembling/fabricating a substrateless hybrid power module assembly. The method includes providing a PCB. Further, the method includes assembling at least one control circuit component on the PCB. Further, the method includes attaching at least one SMT power device on the at least control circuit component Further, the method includes performing at least one device interconnects on the at least one dice using at least one of a wire bonding and a copper strap. Further, the method includes attaching at least one busbar on a bottom portion of the PCB. Further, the method includes attaching at least one isolation layer below the at least one busbar attached on the bottom portion of the PCB. Further, the method includes attaching a heat dissipating layer below the at least one isolation layer. Further, the method includes attaching one of a plastic moulding case and a potting compound on the heat dissipating layer.

The method can be used to improve the effectiveness, reliability, productivity of power electronics systems assembled using discrete power devices and/or bare dice in the high-power electronic system. The method can be used to create custom high current Power Module (PM) and Intelligent Power Module (IPM) without the use of expensive ceramic, metal core, IMS or such substrates. The method can be used to eliminate complex processes, expensive, long lead time materials and allows for high density integration while improving the thermal performance of the system.

The method can be used to combine a control circuit and a power circuit seamlessly and enable high degree of integration of the electronic system while improving the power density, thermal performance and the reliability of the system. The method can be used to allow a traditional SMT mounting techniques, aluminium wire bonds, copper strip bonding solderable interconnection methods or any interconnect methods to make the substrateless hybrid power module assembly. These features make the proposed method enabling a wide range of products and applications. It also maximizes the utilization of power device capabilities and reduce the cost of power delivery. The method allows for flexible designs and quick time to market and to achieve optimized cost of the solutions.

The method can be used to manufacture systems for electric vehicles, traction inverters, chargers, DCDC converters, industrial drives, solar inverters, ups/inverters and for any high-power conversion applications.

In the proposed method, the method can be used to assemble high power electronics modules using the FR4 PCB or suitable grade PCBs (PCB) and high thermal conductivity materials such as aluminium, copper, or ceramic substrate plates or any such suitable materials. The low thermal performance of the PCB is overcome by cutting windows in the PCB under the busbars housing power devices (e.g., SMT or bare dice) and placing high thermal conductivity materials in the windows under the busbars. These high thermal conductivity materials provide an efficient thermal path from the power devices to the heat sink and hence to the ambient. Thereby, the overall structure improves the thermal path to ambient and maximizes the performance of the power devices (such as MOSFETs, IGBTs, SiC devices, GaN devices, diodes etc) used in the substrateless hybrid power module assembly. An appropriate isolation layer with high conductivity (TIM-thermal interface material) to be inserted between a conductor housing power device and the high thermal conductivity materials placed in the PCB windows to impart necessary electrical insulation between the power device and the heat dissipating layer.

The method can be used to eliminate the need for expensive ceramic substrates to build the high power, high current electronic modules. The FR4 PCB used for housing the conductors to mount the power devices can also be used for integrating the control circuit blocks such as microcontrollers, power supplies, gate drivers etc. Hence, the method makes it easier to customize the products and maximize the utilization of the production tooling and production systems. It also eliminates the need for multiple interconnection systems between power devices and control circuits

In the proposed method, the copper or any such high conductivity busbars/pads of sufficient cross section are used to mount the power devices (e.g., SMT or bare dice) and for routing the circuit path to reduce the electrical resistance and hence the power losses. These thick metal busbars/pads used for mounting the power devices (e.g., SMT and/or bare dice) also enhance the thermal performance of the module and the reliability of the system. By way of imparting high thermal capacitance, the busbars/pads help to reduce the peak junction temperatures of the power devices during transient operating conditions. The reduced peak junction temperatures are known to improve the reliability and lifetime of the substrateless hybrid power module assembly. The thick busbars/pads can also be used to form the interconnecting terminals. These terminals also act as heat pipes and help in dissipating heat thereby further reducing the device temperatures.

This combination of the PCB and the high thermal conductivity plates inserted into the PCB cut-outs to be housed in the plastic casing to impart mechanical stability, protect it from humidity and conductive dust. Insert-moulded interconnect elements such as input output terminals, control connectors, sensor elements etc. to be incorporated into module system assembly. A cast aluminium or similar heat dissipating element to be attached to the plastic casing/power module assembly to enhance the thermal performance of the electronic system.

By way of the processes and concepts described herein, the overall assembled module to meet the humidity and temperature cycling needs of the application. The method proposes to build Power Modules (PM) and Integrated Power modules (IPM) without the use of expensive, complex ceramic and similar substrate materials.

Furthermore, the proposed method enables higher degree of integration and flexibility to configure custom features without major design modifications. This allows reconfiguration of module features without major changes to the tools and production processes thus enhancing the productivity and reducing the wastages.

The method also aims to reduce the import dependency and to reduce the time to market of complex power electronic systems. The present method of assembling flexible power assemblies gives the end user to choose the gate drivers and associated components to meet their cost/performance needs. The end user can select the gate drivers from suppliers of their choice with a multitude of supply chain options. The end user can also use the legacy gate driver blocks tested and tried in their products. The module assemblies can house the microcontrollers, sensors and other control components thus reducing the footprint, providing the original equipment manufacturers (OEMs) short assembly cycles, high throughput and also protection against design piracy.

The proposed module construction offers a low thermal resistance path from the device junction to the ambient. This improves the utilization of device capabilities thus reducing the number of power devices connected in parallel to deliver the required current for the system. The method can be used to reduce the complexity and errors in using power devices in a high current system. As a result, the module assemblies eliminate inconsistencies in the systems built with discrete power devices and hence improve the reliability of the systems. The method can be used to enable the end user to create custom configurations and to optimize system design and cost. The module assemblies can be adapted to different circuit and system topologies. The method seeks to provide the end users flexibility and an alternative to expensive PMs and IPMs built using ceramic substrates.

In the proposed method, the PCB with 2 or more layers forms a structural element to provide mechanical and dimensional stability to the busbars on which the devices are mounted. The same PCB can be used to house the control circuits, gate driver circuits and other circuit elements that make up the system. This results in saving expensive, space consuming interconnects between the power elements and the control elements of the system.

In the proposed method, modules with PCB inserted lead frames are used to eliminate substrates and increase current ratings. The proposed method does not rely on the PCB traces to carry the currents. The busbars housing the devices carry the current. Thick busbars (>2500 μm) can be used in the assembly. This reduces the internal resistance of the module and power dissipation in the assembly. The thick busbars under the devices increase the thermal capacitance and the peak junction temperature rise during the transient conditions. Lower peak junction temperatures improve the reliability and the lifetime of the module.

The method can also be used with SMT devices, bare dice with wedge bonding, ball bonding with copper or Aluminium wires, ribbon bonding with Aluminium or copper ribbons and soldered interconnects. The method can be used to reduce the number of thermal interface layers between the device dissipating the power and the ambient that absorbs the dissipated power. Reduced number of interfaces will reduce the thermal resistance and hence the temperature rise of the devices. Reduced temperature rise improves the reliability and the lifetime of the module. The thermal interface material (TIM) characteristics can be matched to the voltage rating of the system and the isolation levels required for the system. By choosing the proper isolation material and the moulding compounds, the voltage rating of the module can be increased to 1200V and above.

The busbars used for housing the devices can be used to form the Power terminals. This reduces the number of elements, space, cost of the system. This method also reduces the internal resistance and inductance of the system.

By way of interconnections, the cables connecting the module terminals (busbars housing the devices) to the external elements (Battery/source and load) also act as heat pipes and carry some of the power dissipated by the devices away from the module hence reducing the temperature rise of the devices. The lower temperature rise improves the reliability and lifetime of the module.

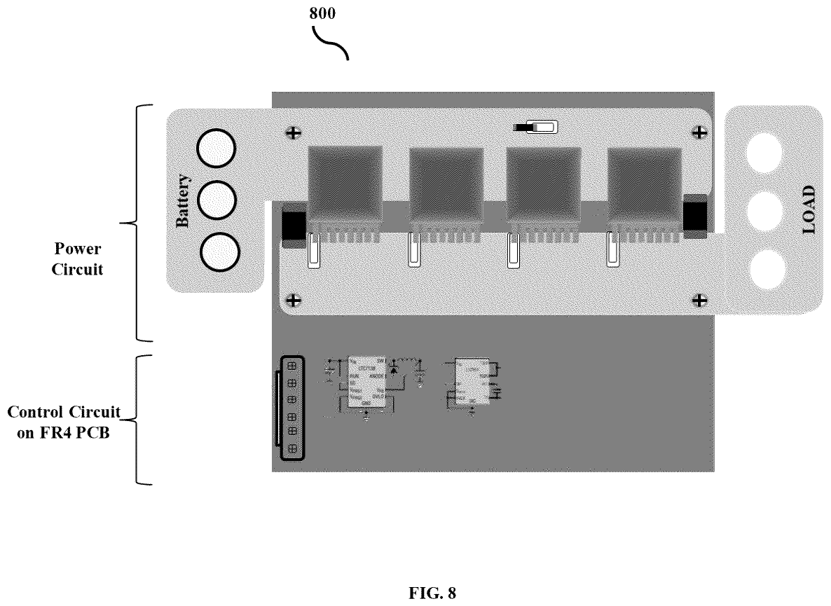

Referring now to the drawings, and more particularly to FIGS. 8 through 48, where similar reference characters denote corresponding features consistently throughout the figures, there are shown embodiments.

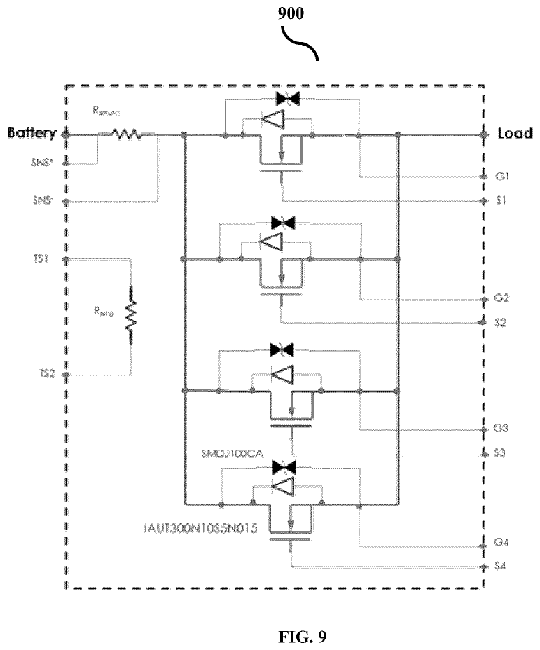

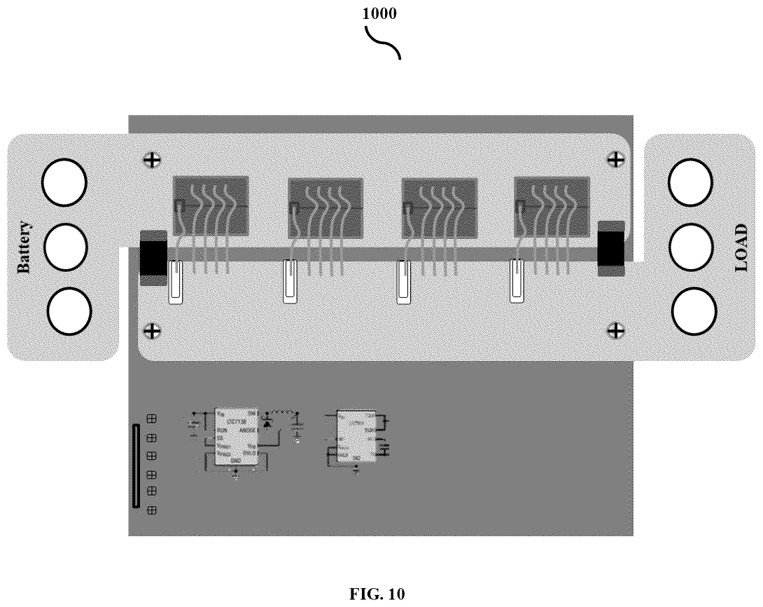

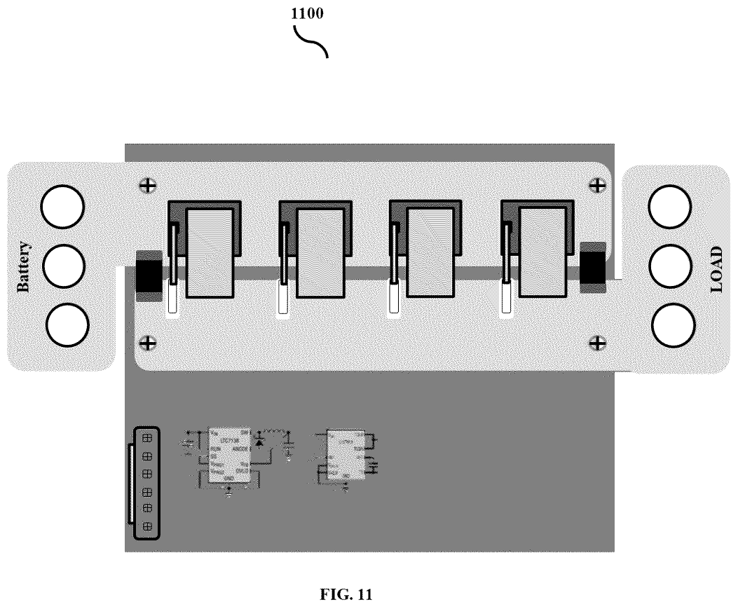

FIG. 8 is an example illustration (800) in which substrateless hybrid power module (e.g., substrateless hybrid power module assembly or the like) with SMT power devices is depicted, according to embodiments as disclosed herein. As shown in the FIG. 8, a top busbar (1304) houses a power device (1306) (e.g., discrete device, die, chip or the like). The PCB (1302) has windows cut out below the busbar housing the power devices (1306). Further, a bottom busbar with embossed inserts (1310) is inserted into the PCB window to provide direct thermal path to the heat sink. Further, a thermal interface material (e.g., electrical isolation) is added between the bottom busbar (1310) and the heat sink. An example schematic circuit diagram (900) of the substrateless hybrid power module with the power devices connected in parallel is depicted in the FIG. 9.

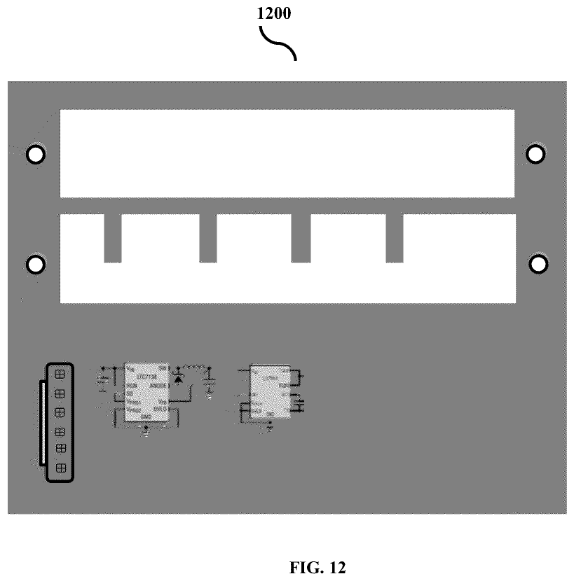

FIG. 10 is an example illustration (1000) in which the substrateless hybrid power module with a chip and a wire bonding is depicted. FIG. 11 is an example illustration (1100) in which the substrateless hybrid power module with copper strap interconnects using a Solderable Front Metal (SFM) die is depicted. FIG. 12 is an example illustration (1200) in which the substrateless hybrid power module PCB windows cut out under the power devices is depicted.

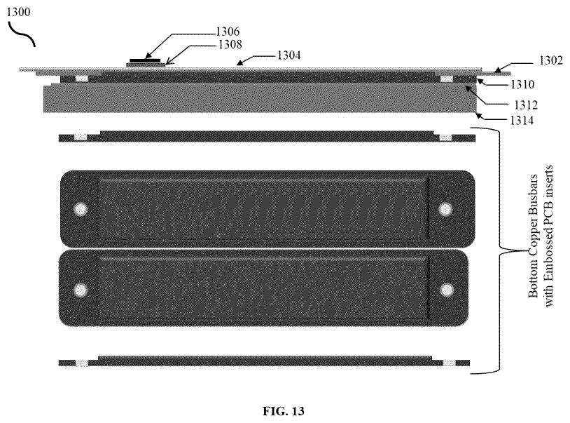

FIG. 13 illustrates a cross sectional view (1300) of the substrateless hybrid power module, according to embodiments as disclosed herein. As shown in the FIG. 13, the PCB (1302), a top copper busbar (1304) (e.g., control circuit component), wherein the top copper busbar is assembled on a portion of the PCB (1302). The power device (1306) (e.g., SMT, die, or the like) is attached on the top copper busbar (1304) using a solder layer. The device interconnects are performed on the deice using a wire bonding or a copper strap. The bottom copper busbar (1310) with embossed PCB inserts is attached on a bottom portion of the PCB (1302) through the windows cut out in it. The isolation layer (1312) is attached below the bottom copper busbar (1310) attached on the bottom portion of the PCB (1302). A heat dissipating layer (1314) is attached below the isolation layer (1312). A plastic moulding case (2702) and a potting compound is attached on the heat dissipating layer (1314).

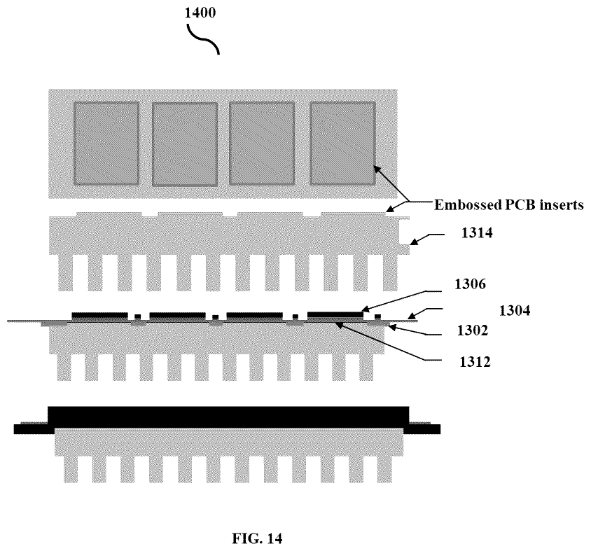

FIG. 14 is an example illustration (1400) in which the substrateless hybrid power module with integrated embossed heatsink is depicted, according to embodiments as disclosed herein. As shown in the FIG. 14, the bottom copper busbar (1310) is eliminated. The heat sink with appropriate embossed ridges is used instead to make contact with the top copper busbar (1304) through the appropriately prepared cut out windows in the PCB. A thermal interface material (e.g., electrical isolation) is added between the top copper busbar (1304) and the embossed heat sink ridges. The heat sink is molded into the plastic and will become the integral part of the module. This method eliminates multiple thermal interfaces and hence will result in better utilization of the silicon devices. This method also reduces the cost of assembling of the substrateless hybrid power module.

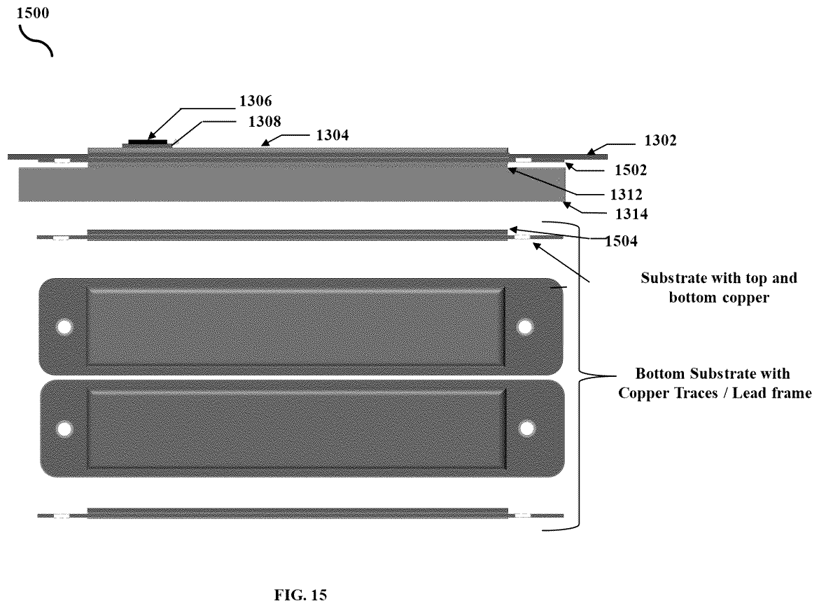

FIG. 15 illustrates a cross sectional view (1500) of the hybrid power module with substrates, according to embodiments as disclosed herein. The PCB (1302), the control circuit component (e.g., top copper busbar (1304)), wherein the control circuit component is assembled on a portion of the PCB (1302). The power device is attached on the control circuit component. The device interconnects are performed on the deice using the SMT, the wire bonding and the copper strap. The bottom copper busbar/Lead frame (1502) is attached to the substrate (e.g., ceramic, metal core, IMS or such) (1504) into the PCB (1302). It is possible to use the ceramic substrate in this method. The size and volume of the ceramic substrate used in this method is significantly lower and improve the thermal dissipation in the assembly and extends the operating voltage range. A heat dissipating layer (1314) is attached to a bottom portion of the substrate (1504). A suitable Thermal Interface Material (TIM) (1312) is placed between bottom substrate (1504) and the heat dissipating layer (1314) and the plastic moulding case (2702) and a potting compound attached on the heat dissipating layer (1314).

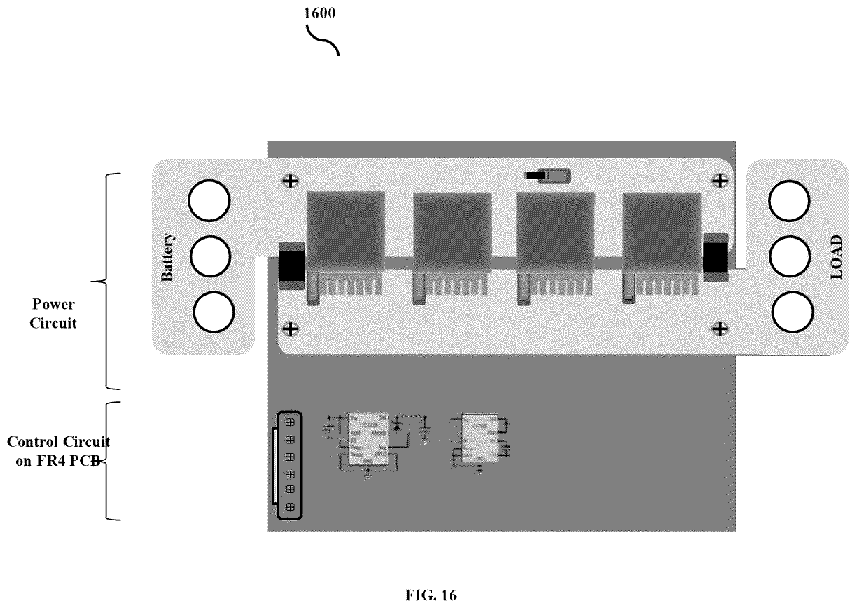

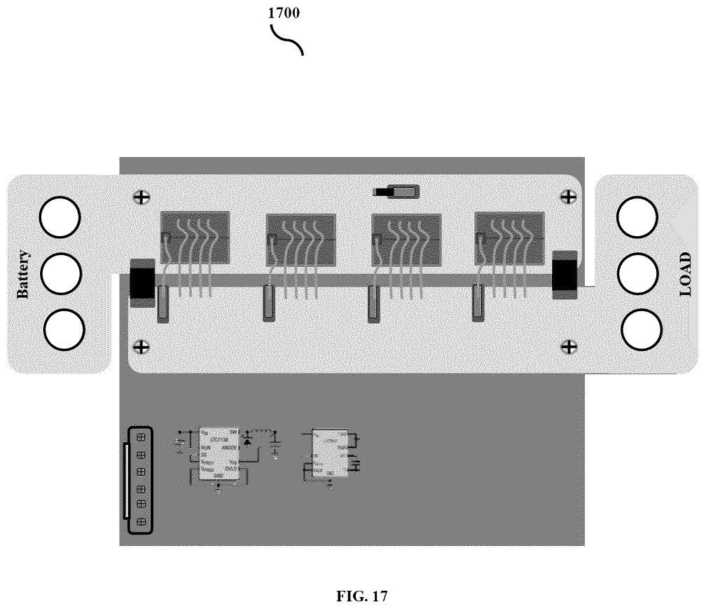

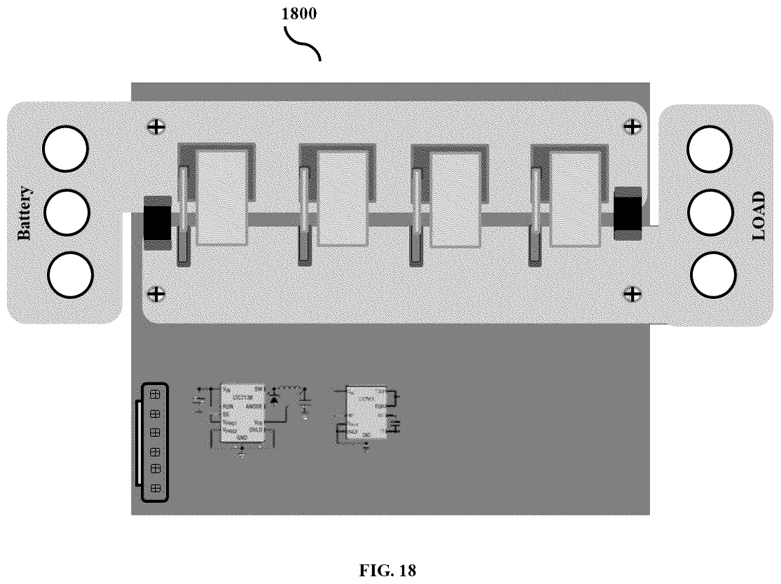

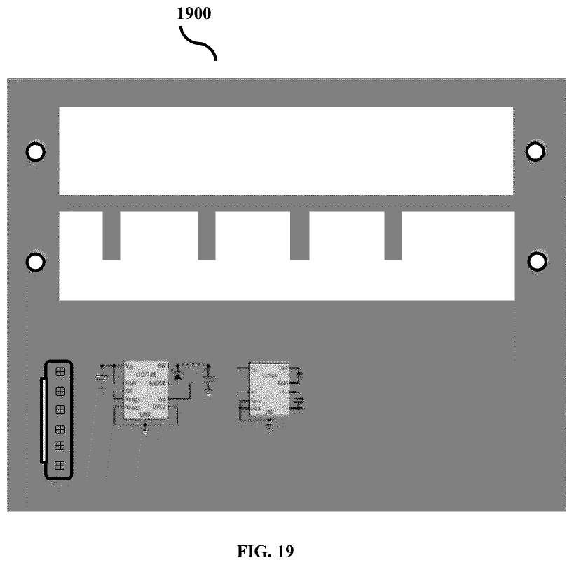

FIG. 16 is an example illustration (1600) in which the substrateless hybrid power module with the SMT power devices is depicted, according to embodiments as disclosed herein. The copper busbar houses the power device (e.g., discrete device, die, chip or the like). The busbar has inserts on the bottom side to pass through the windows cut out in the PCB (1302). The PCB (1302) has windows cut out below the busbar housing the power device. The busbar is inserted into the PCB window to provide direct thermal path to heat dissipating layer. The thermal interface material (1312) (e.g., electrical isolation) is added between the bottom busbar and the heat dissipating layer.

FIG. 17 is another example illustration (1700) in which the substrateless hybrid power module with the chip and the wire bonding is depicted. FIG. 18 is another example illustration (1800) in which the substrateless hybrid power module with the copper strap interconnects using the SFM die is depicted. The embodiments described in FIG. 16-18 use the assembly methods as described in above paragraphs.

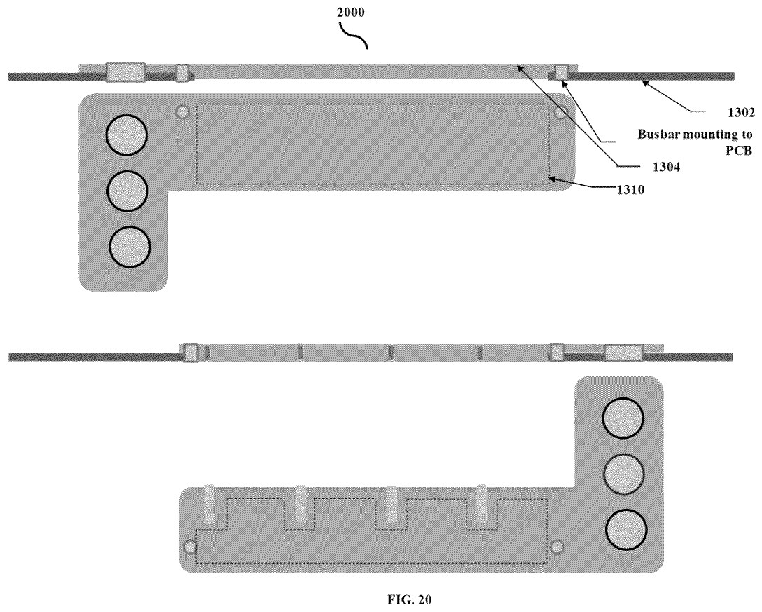

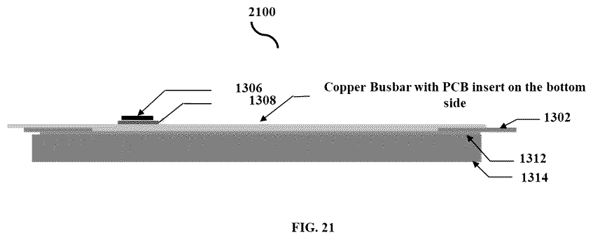

FIG. 19 is an example illustration (1900) in which the substrateless hybrid power module the PCB windows cut out under the power devices is depicted. FIG. 20 illustrates a cross sectional view (2000) of the substrateless hybrid power module with SMT, chip and wire bonding, copper strap interconnection according to embodiments as disclosed herein. FIG. 20 also illustrates the top busbar with embossed PCB inserts on the bottom side of it (1310). The cross-sectional view (2100) of the substrateless hybrid power module is depicted in the FIG. 21.

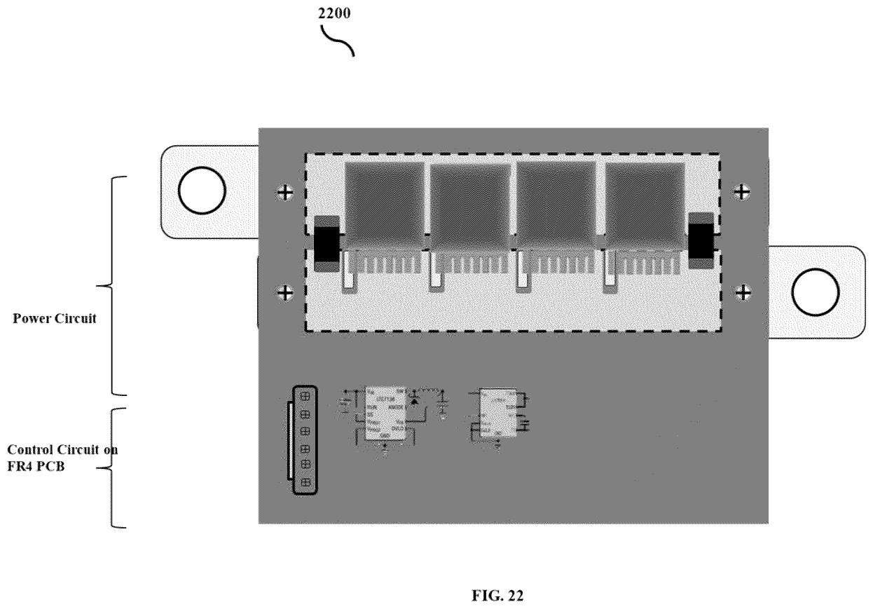

FIG. 22 is an example illustration (2200) in which the substrateless hybrid power module with the SMT power devices is depicted, according to embodiments as disclosed herein. The busbar houses the power devices and the busbar has inserts on the top side to pass through the windows cut out in the PCB (1302). The PCB (1302) has windows cut out for the busbars come to the top of the surface of the PCB (1302). The devices are mounted on the top side of the busbar. The busbars have direct thermal path to heat sink. The thermal interface material (e.g., electrical isolation) is added between the bottom busbar and the heat sink.

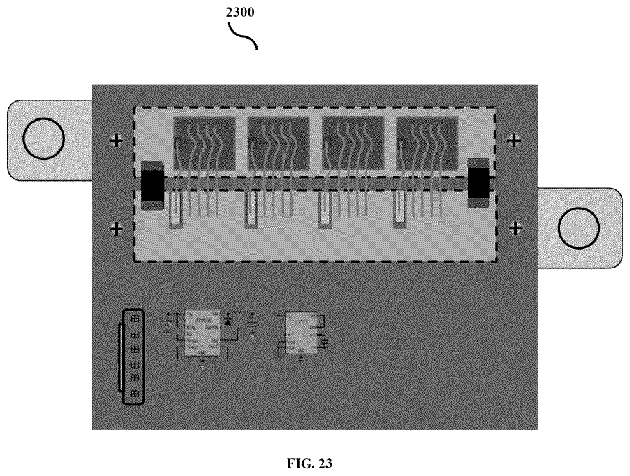

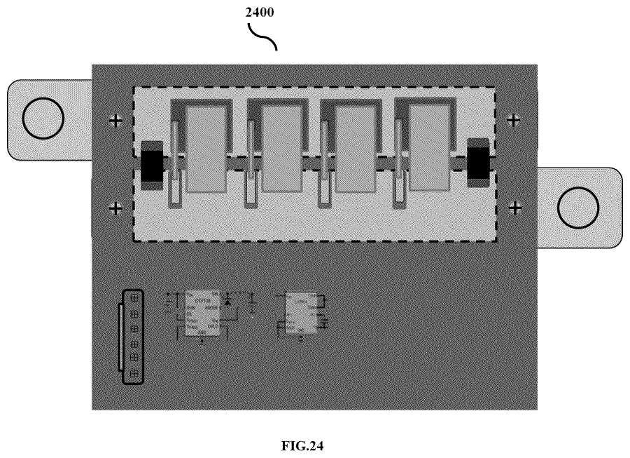

FIG. 23 is an example illustration (2300) in which the substrateless hybrid power module with the chip and wire bonds is depicted. FIG. 24 is another example illustration (2400) in which the substrateless hybrid power module with the copper strap interconnects using the SFM die is depicted. The embodiments described in the FIGS. 22-24 use the assembly methods as described in above paragraphs.

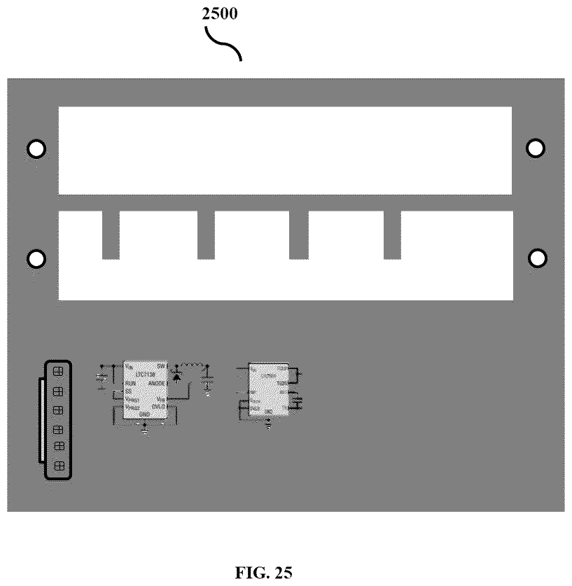

FIG. 25 is an example illustration (2500) in which the substrateless hybrid power module PCB with cutouts is depicted.

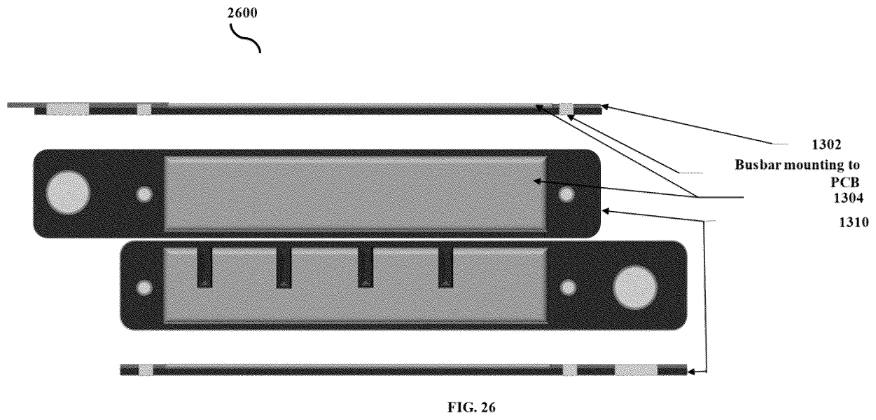

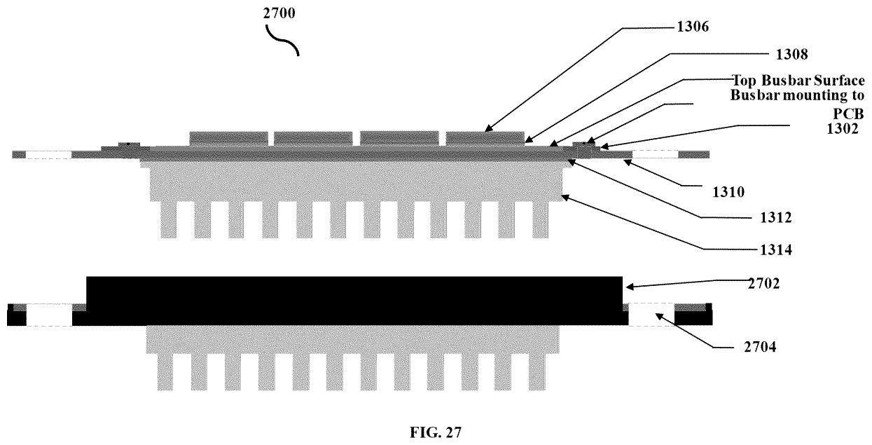

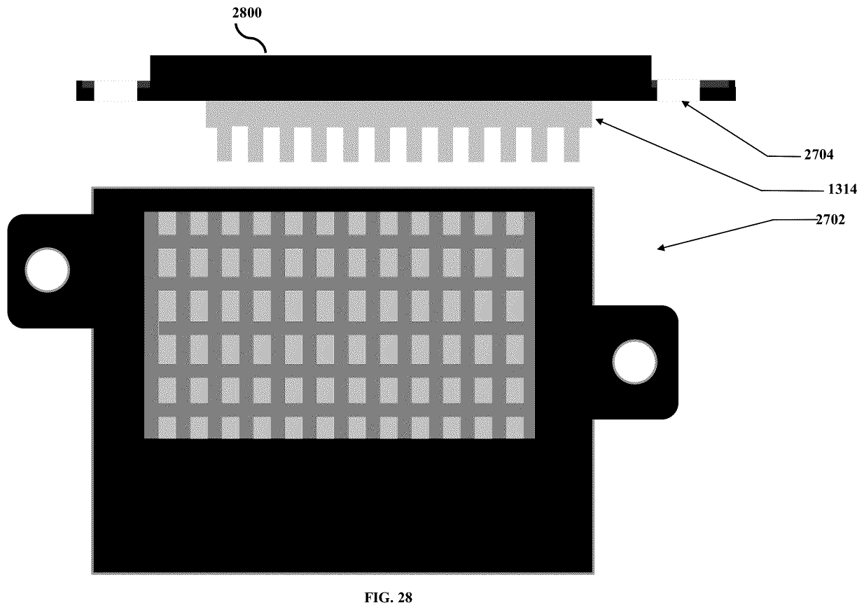

FIG. 26 illustrates a cross sectional view (2600) of the substrateless hybrid power module PCB inserts embossed on the top side copper bus bars. FIG. 27 illustrates a cross sectional view (2700) of the substrateless hybrid power module. FIG. 28 is an example illustration (2800) in which the substrateless hybrid power module with molded plastic casing is depicted.

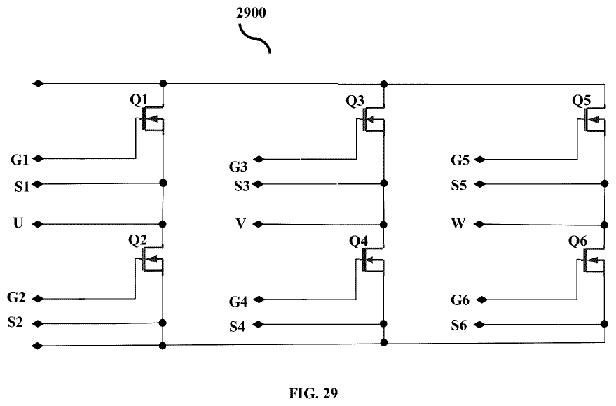

FIG. 29 to FIG. 43 illustrate the examples of implementation of different circuit topologies using embodiments disclosed herein. FIG. 29 is schematic circuit diagram (2900) of a 3-phase inverter power circuit, according to embodiments as disclosed herein.

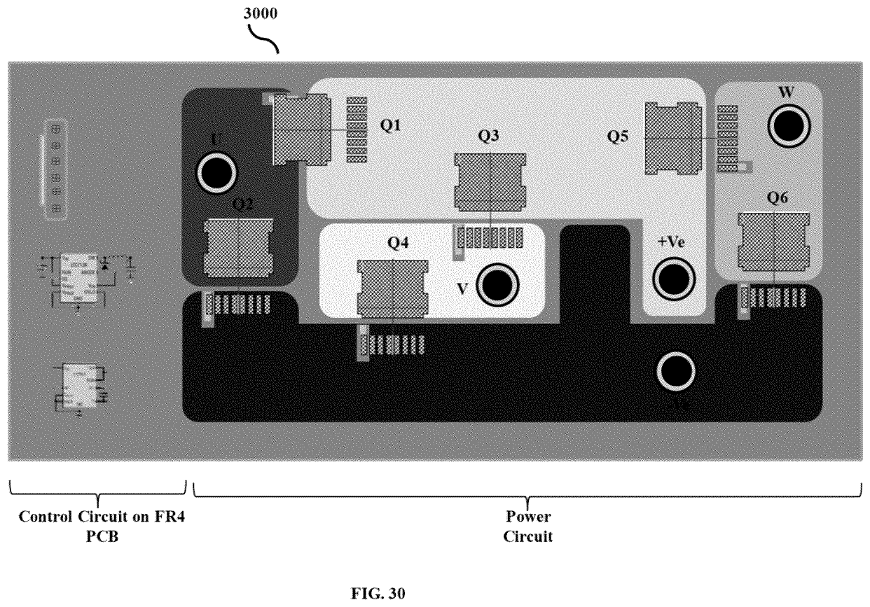

FIG. 30 is an example illustration (3000) in which the 3-phase inverter power module concept separately attached power terminals with the SMT devices is depicted, according to embodiments as disclosed herein.

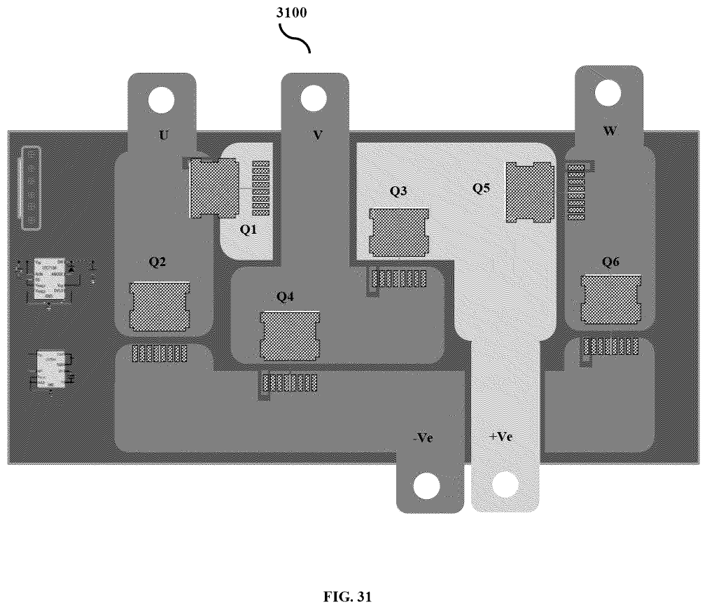

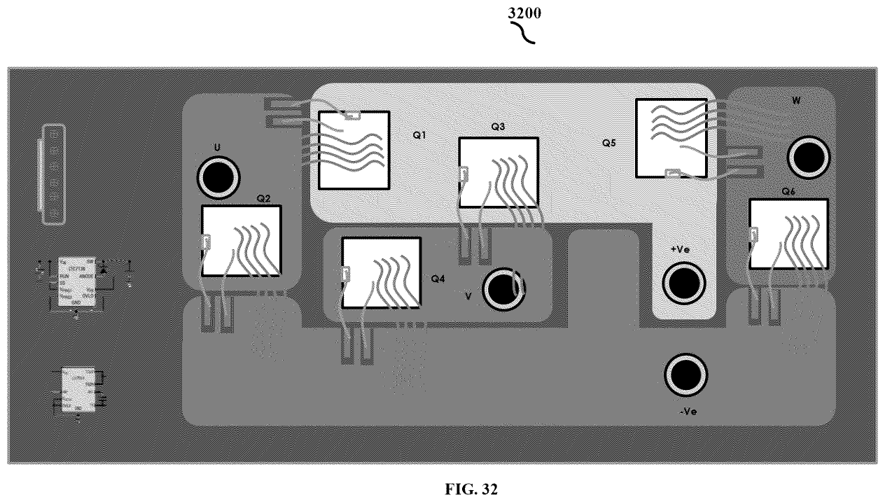

FIG. 31 is an example illustration (3100) in which the 3-phase inverter power module integrated power terminals with the SMT devices is depicted, according to embodiments as disclosed herein.

FIG. 32 is an example illustration (3200) in which the 3-phase inverter power module separately attached power terminals with the chip and wire, according to embodiments as disclosed herein. Other embodiments using copper strap interconnects or other methods are possible.

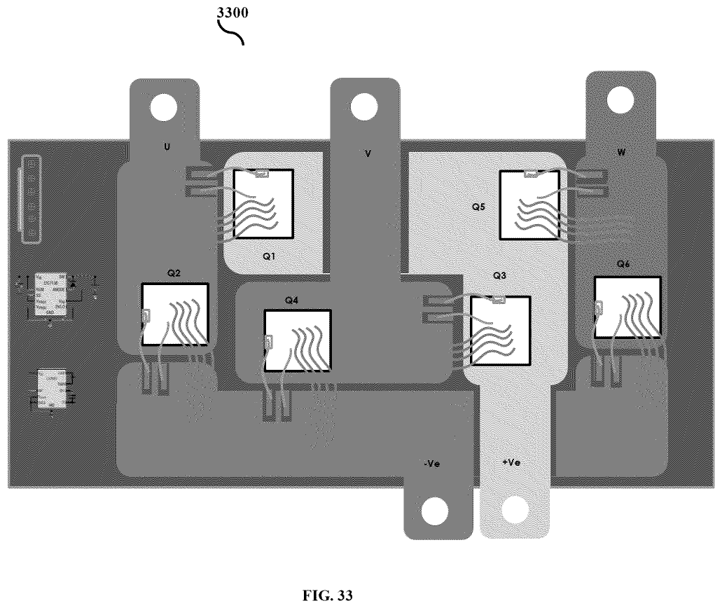

FIG. 33 is an example illustration (3300) in which the 3-phase inverter power module integrated power terminals with bare die or chip and wire bonding, according to embodiments as disclosed herein. Other embodiments using copper strap interconnects or other methods are possible.

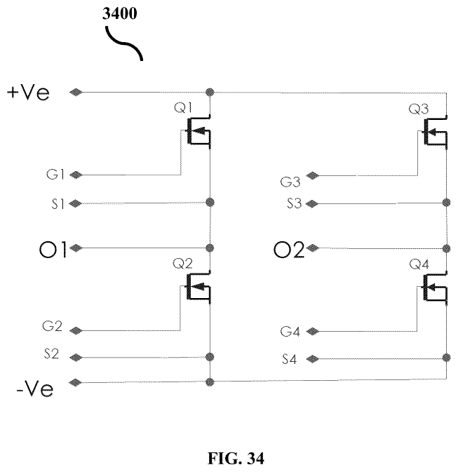

FIG. 34 is circuit diagram (3400) of a full bridge topology used in various system block implementations.

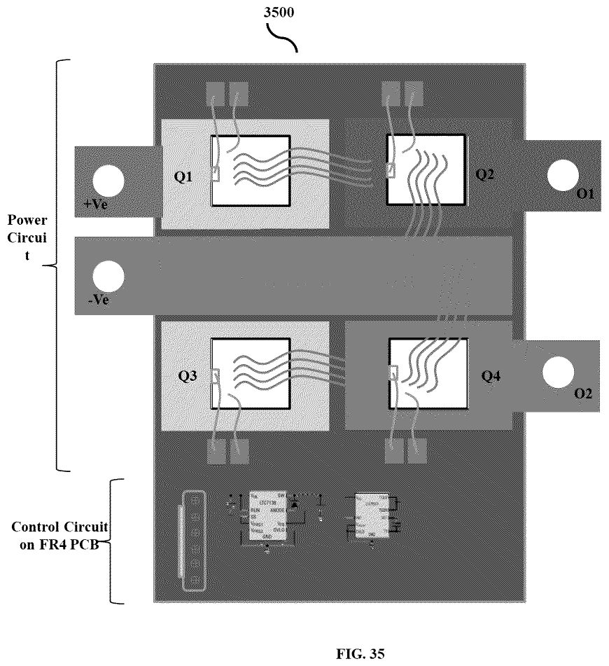

FIG. 35 is an example illustration (3500) in which a full bridge topology with bare die/chip and wire bonds is depicted, according to embodiments as disclosed herein. Other embodiments with the SMT devices, chip/die with the copper strap interconnects can be implemented using the assembly methods disclosed herein.

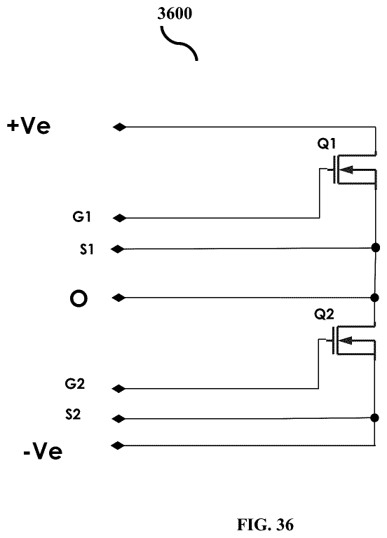

FIG. 36 is circuit diagram (3600) of a half bridge topology used in various system block implementations.

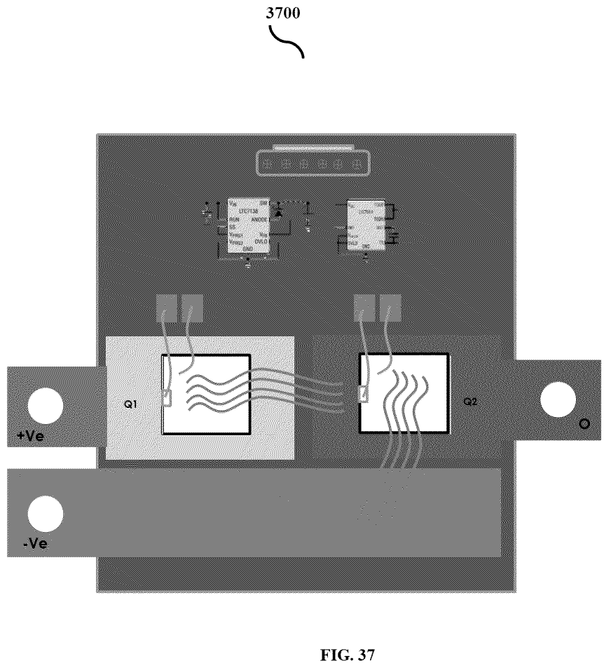

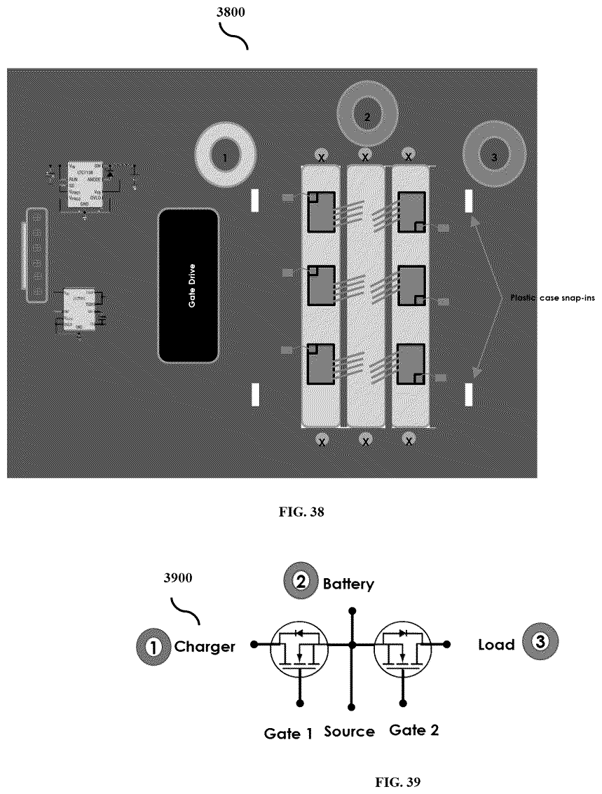

FIG. 37 is an example illustration (3700) in which a full bridge topology with bare die/chip and wire bonds is depicted, according to embodiments as disclosed herein. Other embodiments with SMT devices, Chip/die with copper strap interconnects can be implemented using the assembly methods disclosed herein.

FIG. 38 is an example illustration (3800) in which a bidirectional switch with bare die/chip and wire bonds is depicted, according to embodiments as disclosed herein.

### Other Embodiments

SMT devices, Chip/die with copper strap interconnects can be implemented using the assembly methods disclosed herein.

FIG. 39 is circuit diagram (3900) of the bidirectional switch topology used in various system block implementations.

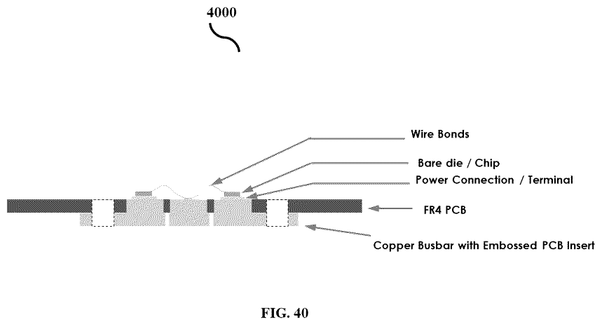

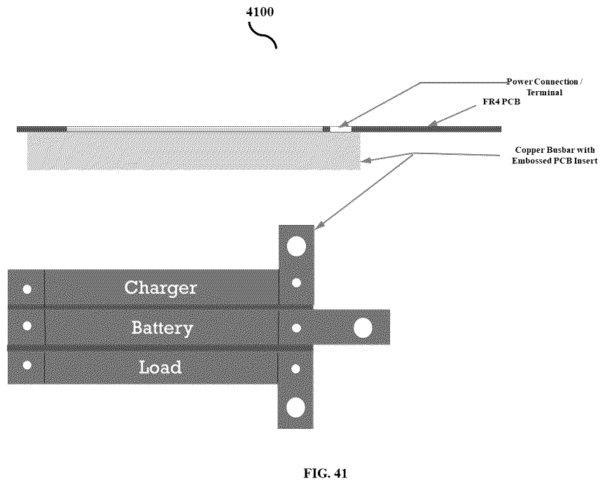

FIG. 40 is front view (4000) of a lead frame assembly, for the bidirectional switch according to embodiments as disclosed herein. FIG. 41 is a side view (4100) of a lead frame assembly example along with details, according to embodiments as disclosed herein.

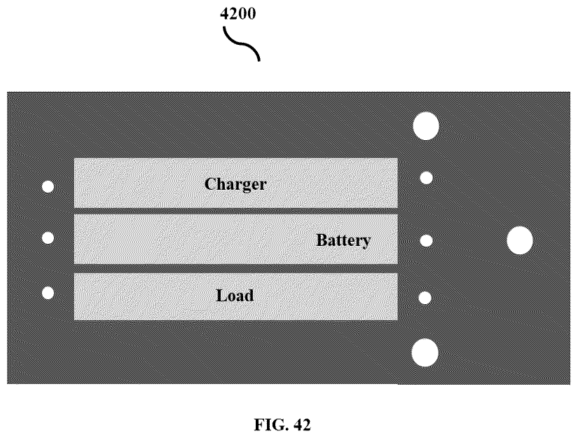

FIG. 42 is an example illustration (4200) in which the lead frame assemble on FR4 PCB is depicted, according to embodiments as disclosed herein.

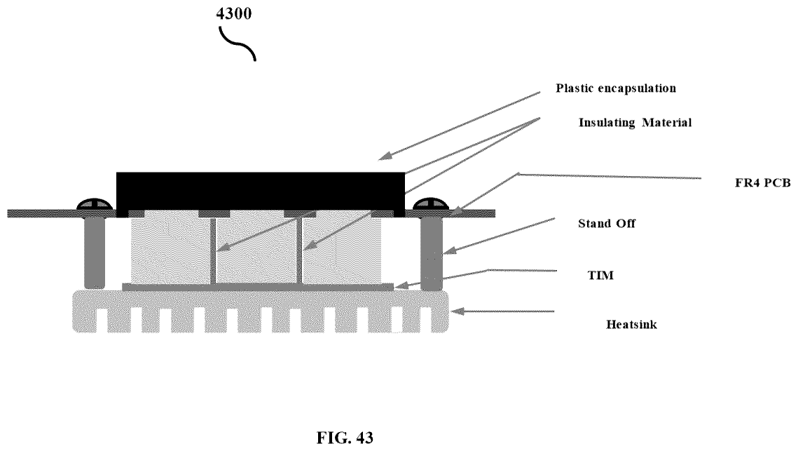

FIG. 43 is a cross sectional view (4300) of bidirectional switch assembly stack details, according to embodiments as disclosed herein.

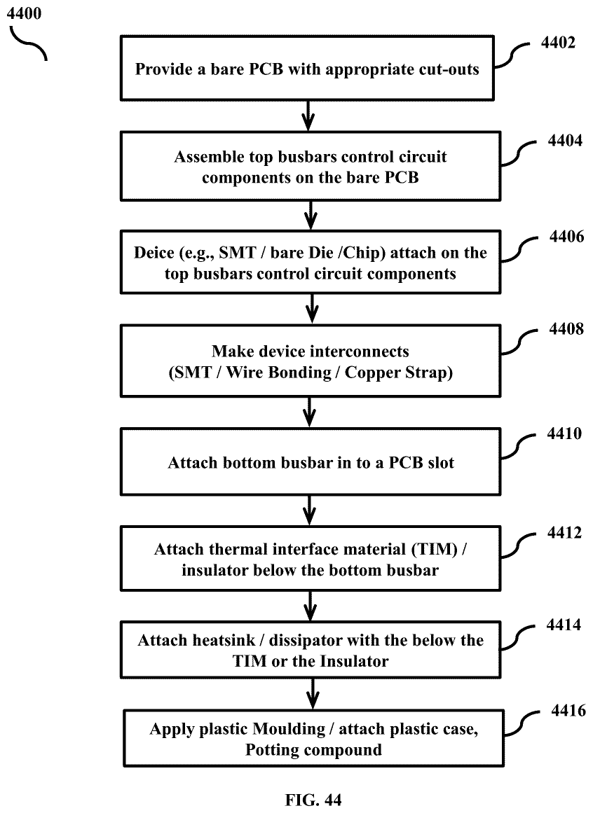

FIG. 44-FIG. 48 are flow charts illustrating a method (4400-4800) for assembling/fabricating the high power electronics modules using a FR4 or suitable grade PCBs (PCB), according to embodiments as disclosed herein.

As shown in the FIG. 44, at 4402, the method includes providing the bare PCB with appropriate cut-outs. In order to provide the appropriate cut-outs, the windows are marked through an electrical/mechanical computer-aided design (CAD) tool for precise location and size of the windows. The windows can be cut using milling operation during the PCB fabrication. At 4404, the method includes assembling the top busbars control circuit components on the bare PCB. At 4406, the method includes placing the deice (e.g., SMT, bare die, chip or the like) on the top busbars control circuit components. At 4408, the method includes performing the device interconnects using the SMT, wire bonding and/or the copper strap. At 4410, the method includes attaching the bottom busbars in the bare PCB. At 4412, the method includes attaching TIM/Insulator below the bottom busbar. At 4414, the method includes attaching the heatsink or the dissipator below the TIM or the insulator. At 4416, the method includes applying the plastic moulding or attaching plastic case, and or the potting compound on the heatsink or the dissipator.

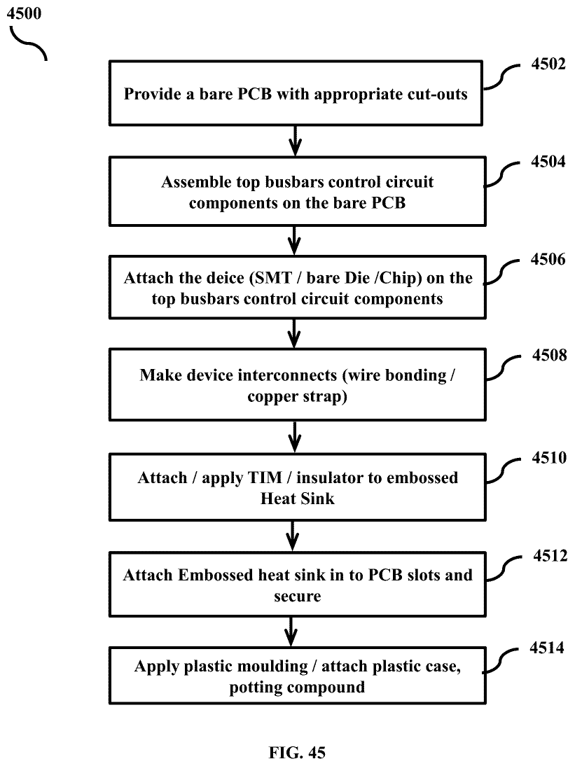

As shown in the FIG. 45, at 4502, the method includes providing the bare PCB with appropriate cut-outs. At 4504, the method includes assembling the top busbars control circuit components on the bare PCB. At 4506, the method includes attaching the deice (e.g., SMT, bare die, chip or the like). At 4508, the method includes creating the device interconnects using the SMT, wire bonding and the copper strap. At 4510, the method includes attaching or applying the TIM or the insulator to the embossed heat sink. At 4512, the method includes attaching the embossed heat sink into the PCB. At 4514, the method includes applying plastic moulding or the attach plastic case and potting compound.

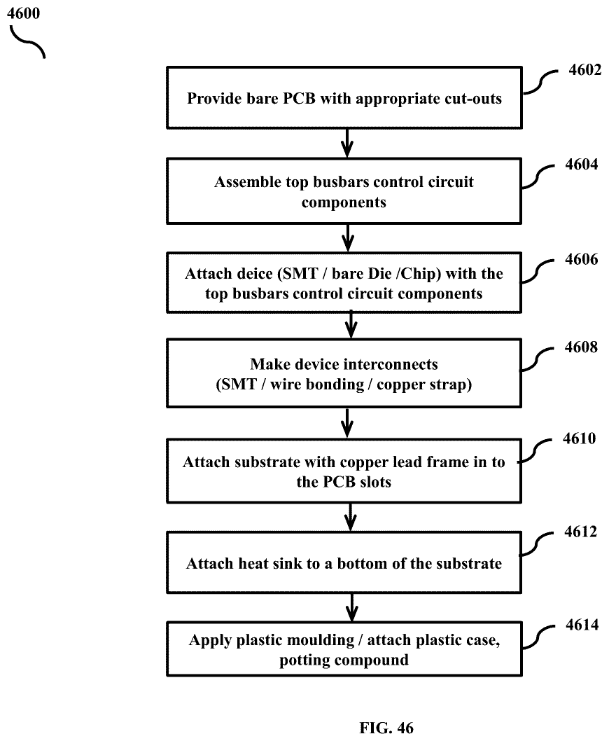

As shown in the FIG. 46, at 4602, the method includes providing the bare PCB with appropriate cut-outs. At 4604, the method includes assembling the top busbars control circuit components on the PCB. At 4606, the method includes attaching the deice (e.g., SMT, bare die, chip or the like). At 4608, the method includes creating the device interconnects using SMT/the wire bonding/the copper strap. At 4610, the method includes attaching the substrate with copper lead frame into the PCB cut-outs. In an embodiment, the copper lead frame comprises either milled/machined copper busbars to form the embossed inserts. They can also be diecast/moulded to required specifications. The copper busbars/Lead frames can be attached to the FR4 PCB via soldering process or mechanical fitments using clips, screws or any other appropriate means to secure them to the FR4 PCB. At 4612, the method includes attaching the heat sink to the bottom of the substrate. At 4614, the method includes applying the plastic moulding or attaching the plastic case and the potting compound.

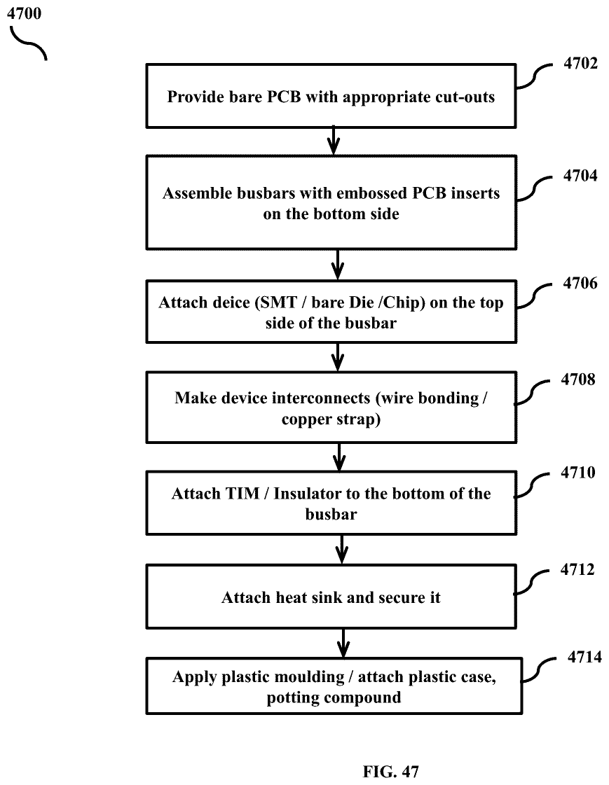

As shown in the FIG. 47, at 4702, the method includes providing the PCB with appropriate cut-outs. At 4704, the method includes assembling the busbars with the embossed PCB inserts on the bottom side. At 4706, the method includes placing the devices (e.g., SMT, bare die, chip or the like) on the top side of the busbar. At 4708, the method includes performing the device interconnects using SMT, the wire bonding or the copper strap. At 4710, the method includes attaching the TIM/Insulator below the bottom side of the busbar. At 4712, the method includes attaching the heatsink or the dissipator below the TIM or the insulator. At 4714, the method includes applying the plastic moulding or attaching plastic case, or the potting compound on the heatsink or the dissipator.

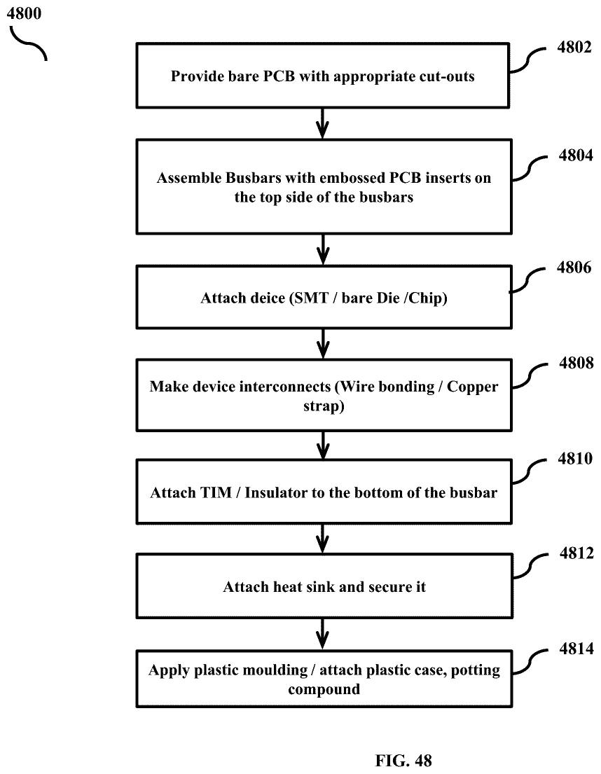

As shown in the FIG. 48, at 4802, the method includes providing the bare PCB with appropriate cut-outs. At 4804, the method includes assembling the busbars with the embossed PCB inserts on the top side of the busbars. At 4806, the method includes placing the devices (e.g., SMT, bare die, chip or the like) on the top side of the busbars. At 4808, the method includes performing the device interconnects using SMT, the wire bonding or copper strap. At 4810, the method includes attaching TIM/Insulator below the busbar. At 4812, the method includes attach heatsink or the dissipator below the TIM or the Insulator. At 4814, the method includes applying the plastic moulding or attaching plastic case, or the potting compound on the heatsink or the dissipator.

The method can be used to improve the effectiveness, reliability, productivity of power electronics systems assembled using discrete power devices and/or bare dice in the high power electronic system. The method can be used to create custom high current PM and the IPM without the use of expensive ceramic substrates. The method can be used to eliminate complex processes, expensive, long lead time materials and allows for high density integration while improving the thermal performance of the system.

The method can be used to combine the control circuit and the power circuit seamlessly and enable high degree of integration of the electronic system while improving the power density, thermal performance and the reliability of the system. The method can be used to allow the traditional SMT mounting technique, the aluminium wire bonds, the copper strip bonding solderable interconnection methods or any interconnect methods to make a circuit. These features make the proposed method enable a wide range of products and applications. It also maximizes the utilization of power device capabilities and reduce the cost of power delivery. The method allows for flexible designs and quick time to market and to achieve optimized cost of the solutions.

In an embodiment, the method can be used to assemble high power electronics modules using the FR4 PCB or suitable grade PCBs (PCB) and high thermal conductivity materials such as aluminium, copper, or ceramic substrate plates or any such suitable materials. The low thermal performance of PCB is overcome by cutting windows in the PCB under the busbars housing power devices (SMT or bare dice) and placing high thermal conductivity materials in the windows under the busbars. These high thermal conductivity materials provide an efficient thermal path from the power devices to the heat sink and hence to the ambient. Thereby, the overall structure improves the thermal path to ambient and maximizes the performance of the power devices (such as MOSFETs, IGBTs, SiC devices, GaN devices, diodes etc) used in the system. An appropriate thermal interface material to be inserted between the conductor housing power device and the high thermal conductivity materials placed in the PCB windows to impart necessary electrical insulation between the power device and the heat dissipating system.

The method can be used to eliminate the need for expensive ceramic substrates to build the high power, high current electronic modules. The FR4 PCB used for housing the conductors to mount the power devices can also be used for integrating the control circuit blocks such as microcontrollers, power supplies, gate drivers etc. Hence, the method makes it easier to customize the products and maximize the utilization of the production tooling and production systems. It also eliminates the need for multiple interconnection systems between power devices and control circuits

In the proposed method, the copper or any such high conductivity busbars/pads of sufficient cross section are used to mount the power devices (SMT or bare dice) and for routing the circuit path to reduce the electrical resistance and hence the power losses. These thick metal busbars/pads used for mounting power devices (SMT and/or bare dice) also enhance the thermal performance of the module and the reliability of the system. By way of imparting high thermal capacitance, the busbars/pads help to reduce the peak junction temperatures of the power devices during transient operating conditions. The reduced peak junction temperatures are known to improve the reliability and lifetime of the systems. The thick busbars/pads can also be used to form the interconnecting terminals. These terminals also act as heat pipes and help in dissipating heat thereby further reducing the device temperatures.

This combination of PCB and the high thermal conductivity plates inserted into the PCB cut-outs to be housed in plastic casing to impart mechanical stability, protect it from Humidity and conductive dust. Insert-moulded interconnect elements such as input output terminals, control connectors, sensor elements etc. to be incorporated into module system assembly. A cast aluminium or similar heat dissipating element can be attached to the plastic casing/power module assembly to enhance the thermal performance of the electronic system.

By way of the processes and concepts described herein, the overall assembled module meets the humidity and temperature cycling needs of the application. The method proposes to build Power Modules (PM) and Intelligent Power Modules (IPM), without the use of expensive, complex ceramic and similar substrate materials.

Furthermore, the proposed method enables higher degree of integration and flexibility to configure custom features without major design modifications. This allows reconfiguration of module features without major changes to the tools and production processes thus enhancing the productivity and reducing the wastages.

In the proposed method, the PCB with 2 or more layers forms a structural clement to provide mechanical and dimensional stability to the busbars on which the devices are mounted. The same PCB can be used to house the control circuits, gate driver circuits and other circuit elements that make up the system. This results in saving expensive, space consuming interconnects between the power elements and the control elements of the system.

In the proposed method, modules with insert moulded lead frames are used to eliminate substrates and increase current ratings. The proposed method does not rely on the PCB traces to carry the currents. The busbars housing the devices carry the current. Thick busbars (>2500 μm) can be used in the assembly. This reduces the internal resistance of the module and power dissipation in the assembly. The thick busbars under the devices increase the thermal capacitance and the peak junction temperature rise during the transient conditions. Lower peak junction temperatures improve the reliability and the lifetime of the module.

The method can also be used with wedge bonding, ball bonding with copper or Aluminium wires, ribbon bonding with Aluminium or copper ribbons and soldered interconnects.

The method can be used to reduce the number of thermal interface layers between the device dissipating the power and the ambient that absorbs the dissipated power. Reduced number of interfaces will reduce the thermal resistance and hence the temperature rise of the devices. Reduced temperature rise improves the reliability and the lifetime of the module. The thermal interface material (TIM) characteristics can be matched to the voltage rating of the system and the isolation levels required for the system. By choosing the proper isolation material and the moulding compounds, the voltage rating of the module can be increased to 1200V and above. The busbars used for housing the devices can be used to form the Power terminals. This reduces the number of elements, space, cost of the system. This method also reduces the internal resistance and inductance of the system.

By way of interconnections, the cables connecting the module terminals (busbars housing the devices) to the external elements (Battery/source and load) also act as heat pipes and carry some of the power dissipated by the devices away from the module hence reducing the temperature rise of the devices. Lower temperature rise improves the reliability and lifetime of the module.

The method also aims to reduce the import dependency and to reduce the time to market of complex power electronic systems.

Embodiments herein give the end user to choose the gate drivers and associated components to meet their cost/performance needs. The end user can select the gate drivers from suppliers of their choice with a multitude of supply chain options. The end user can also use the legacy gate driver blocks tested and tried in their products. The module assemblies can house the microcontrollers, sensors and other control components thus reducing the footprint, providing the OEMs protection against design piracy.

The proposed module construction offers a low thermal resistance path from the device junction to the ambient. This reduces the number of power devices connected in parallel to deliver the required current for the system. Embodiments herein also aim to reduce the complexity and errors in using power devices in a high current system. As a result, the module assemblies described here eliminate inconsistencies in the systems built with discrete power devices and hence improve the reliability of the systems. Embodiments herein also enable the end user to create custom configurations, ratings to optimize system design and cost. The module assemblies can be adapted to different circuit and system topologies. The method seeks to provide the end users flexibility and an alternative to expensive PMs and IPMs built using ceramic substrates.

The assembly process is flexible and is not limited to what is illustrated in the patent application. Other topologies can be assembled using the proposed methods. The Silicon MosFETs, the IGBTs, the diodes, SiC MosFETs, SiC Diodes, GaN devices can be assembled using the proposed method.

The power devices with voltage rating from 30V to 1700V and above can be assembled using the proposed method with appropriate isolation techniques. The power devices with current rating from 10 A to more than 1000 A can be assembled using the proposed method with appropriate busbar and interconnect techniques. Both high power devices and low power control devices can be assembled using the proposed method in the same package to improve the performance and reduce the volume. The method also reduces the interconnects in the system to improve the reliability.

The various actions, acts, blocks, steps, or the like in the method (4400-4800) may be performed in the order presented, in a different order or simultaneously. Further, in some embodiments, some of the actions, acts, blocks, steps, or the like may be omitted, added, modified, skipped, or the like without departing from the scope of the embodiments herein.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of embodiments and examples, those skilled in the art will recognize that the embodiments and examples disclosed herein can be practiced with modification within the spirit and scope of the embodiments as described herein.

We claim:

1. A method (4400-4800) for fabricating a substrateless hybrid power module assembly, comprising:
assembling (4404-4804) at least one control circuit component on a printed circuit board (PCB) (1302);
attaching (4406-4806) at least one power device on the at least control circuit component; and
performing (4408-4808) at least one device interconnects on the at least one device using at least one of a Surface-mount technology (SMT), wire bonding, a ribbon bonding, and a copper strap.

2. The method as claimed in claim 1, wherein the method comprises:
attaching (4410) at least one busbar on a bottom portion of the PCB (1302);
attaching (4412) at least one isolation layer (1312) below the at least one busbar attached on the bottom portion of the PCB (1302);
attaching (4414) a heat dissipating layer (1314) below the at least one isolation layer (1312); and
attaching (4416) one of a plastic moulding case (2702) and a potting compound on the heat dissipating layer (1314).

3. The method as claimed in claim 1, wherein the method comprises:
attaching (4510) at least one isolation layer (1312) to an embossed heat dissipating layer (1314);
attaching (4512) the embossed heat dissipating layer (1314) into cutouts associated with the PCB (1302); and
attaching (4514) one of a plastic moulding case (2702) and a potting compound on the heat dissipating layer (1314).

4. The method as claimed in claim 1, wherein the method comprises:
attaching (4610) a substrate (1502) with a copper lead frame (1504) into cutouts associated with the PCB (1302);
attaching (4612) a heat dissipating layer (1314) to a bottom portion of the substrate (1502); and
attaching (4614) one of a plastic moulding case (2702) and a potting compound on the heat dissipating layer (1314).

5. The method as claimed in claim 4, wherein the substrate (1502) comprises at least one of a ceramic substrate, a metal core PCB, and an IMS substrate.

6. The method as claimed in claim 1, wherein the at least one control circuit component comprises one of a top busbar control circuit component (1304) and a bottom busbar control circuit component (1310).

7. The method as claimed in claim 6, wherein the top busbar control circuit component (1304) is provided with at least one embossed PCB insert, wherein the bottom busbar control circuit component (1310) is provided with at least one embossed PCB insert.

8. The method as claimed in claim 1, wherein the at least one power device comprises a SMT, a bare die, a chip, a discrete device, a metal-oxide-semiconductor field-effect transistor (MOSFET), an insulated-gate bipolar transistor (IGBT), a diode, and a gallium nitride (GaN) device.

9. The method as claimed in claim 4, wherein at least one isolation layer (1312) comprises at least one a TIM and an insulator, and wherein the heat dissipating layer (1314) comprises a heatsink and a heat dissipater.

10. The method as claimed in claim 1, wherein the PCB (1302) comprises a windows cut out below the busbar, wherein the windows are marked through a computer-aided design (CAD) tool for precise location and size of the windows cut, wherein the windows is cut using a milling operation during the PCB fabrication.

11. The method as claimed in claim 10, wherein the copper lead frame (1504) comprises at least one of a milled copper busbars and a machined copper busbars to form embossed inserts, wherein the copper lead frame (1504) is diecast or moulded to required specifications, wherein the at least one of the copper busbars and the lead frames is attached to the PCB via a soldering process or mechanical fitments using a connecting unit to secure the lead frame to the PCB, wherein the connecting unit comprises a clip and screws.

12. A substrateless hybrid power module assembly, comprising:
a printed circuit board (PCB) (1302);
at least one control circuit component, wherein the at least one control circuit component is assembled on the PCB (1302);
at least one power device, wherein the at least one power device is attached on the at least control circuit component; and
at least one device interconnects performed on the at least one Surface-mount technology (SMT) and a dice using at least one of a wire bonding, a ribbon bonding and a copper strap.

13. The substrateless hybrid power module assembly as claimed in claim 12, wherein the substrateless hybrid power module assembly comprises:
at least one busbar, wherein the at least one busbar is attached on a bottom portion of the PCB (1302);
at least one isolation layer (1312), wherein the at least one isolation layer (1312) is attached below the at least one busbar attached on the bottom portion of the PCB (1302);
a heat dissipating layer (1314) attached below the at least one isolation layer (1312); and
one of a plastic moulding case (2702) and a potting compound attached on the heat dissipating layer (1314).

14. The substrateless hybrid power module assembly as claimed in claim 12, wherein the substrateless hybrid power module assembly comprises:
at least one isolation layer (1312) attached to an embossed heat dissipating layer (1314);
the embossed heat dissipating layer (1314) attached into the PCB (1302); and
one of a plastic moulding case (2702) and a potting compound attached on the heat dissipating layer (1314).

15. The substrateless hybrid power module assembly as claimed in claim 12, wherein the substrateless hybrid power module assembly comprises:
a substrate (1502) attached with a copper lead frame (1504) into the PCB (1302) cut outs from bottom surface;
a heat dissipating layer (1314) attached to a bottom portion of the substrate (1502); and
one of a plastic moulding case (2702) and a potting compound attached on the heat dissipating layer (1314).

16. The substrateless hybrid power module assembly as claimed in claim 15, wherein the substrate (1502) comprises at least one of a ceramic substrate, a metal core PCB, and an IMS substrate. The substrates help to extend the voltage ratings of the system.

17. The substrateless hybrid power module assembly as claimed in claim 12, wherein the at least one control circuit component comprises one of a top busbar control circuit component (1304) and a bottom busbar control circuit component (1310).

18. The substrateless hybrid power module assembly as claimed in claim 17, wherein the top busbar control circuit component (1304) is provided with at least one embossed PCB insert, wherein the bottom busbar control circuit component (1310) is provided with at least one embossed PCB insert.

19. The substrateless hybrid power module assembly as claimed in claim 12, wherein the at least one power device comprises a SMT, a bare die, a chip, a discrete device, a metal-oxide-semiconductor field-effect transistor (MOSFET), an insulated-gate bipolar transistor (IGBT), a diode, and a gallium nitride (GaN) device.

20. The substrateless hybrid power module assembly as claimed in claim 15, wherein at least one isolation layer (1312) comprises at least one a TIM and an insulator, and wherein the heat dissipating layer (1314) comprises a heatsink and a heat dissipater.

21. The substrateless hybrid power module assembly as claimed in claim 12, wherein the PCB (1302) comprises windows cut out below the busbar, wherein the windows are marked through a computer-aided design (CAD) tool for precise location and size of the windows cut, wherein the windows are cut using a milling operation during the PCB fabrication.

22. The substrateless hybrid power module assembly as claimed in claim 15, wherein the copper lead frame (1504) comprises at least one of a milled copper busbars and a machined copper busbars to form embossed inserts, wherein the copper lead frame (1504) is diecast or moulded to required specifications, wherein the at least one of the copper busbars and the lead frames is attached to the PCB via a soldering process or mechanical fitments using a connecting unit to secure the lead frame to the PCB, wherein the connecting unit comprises a clip and screws.
